(19) United States
(12) Patent Application Publication
(10) Pub. No.: US 2025/0301848 A1
(43) Pub. Date: Sep. 25, 2025

(54) PASSIVE OPTICAL ELEMENTS FOR COVERING FOR DEFECTIVE PIXELS IN DISPLAYS AND METHODS RELATED THERETO

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US); Gaius Gillman Fountain, JR., Youngsville, NC (US)

(21) Appl. No.: 18/960,657

(22) Filed: Nov. 26, 2024

Related U.S. Application Data
(60) Provisional application No. 63/568,867, filed on Mar. 22, 2024.

(51) Int. Cl. H10H 29/856; H01L 25/075; H10H 29/14

(52) U.S. Cl. CPC H10H 29/856; H01L 25/0753; H10H 29/142

(57) ABSTRACT

A passive optical element is formed and attached to surface of two or more LEDs of a display. The passive optical element redistributes light emitted from a first LED to exit the display in a first and second region of the display. The first region of the display corresponds to the first LED, and the second region of the display corresponds to the second LED.

### CROSS-REFERENCE TO RELATED APPLICATION

The present disclosure claims the benefit of U.S. Provisional Patent Application No. 63/568,867, filed Mar. 22, 2024, which is hereby incorporated by reference herein in its entirety.

### FIELD

The present disclosure relates to display devices and methods of manufacturing the same.

### BACKGROUND

Micro light emitting diode (microLED, micro-LED, μLED, or μ-LED) displays may provide benefits of higher resolution and increased brightness when compared to conventional display technologies. Unfortunately, current manufacturing processes used to address defective pixels on a display may be prohibitively expensive and/or consume valuable area on a display. For example, to fix a defective LED, an LED may be removed and replaced with a new LED, or pixels may have redundancy pads and new micro-LEDs may be mounted at open locations. However, removing an LED and/or replacing it with another LED is time consuming and may not be possible or practical as pixel sizes go down in size, and having redundancy pads on pixels may take up valuable area on a display. Accordingly, there exists a need in the art for improved microLED displays and methods of manufacturing the same.

### SUMMARY

Embodiments herein provide for passive optical elements in displays and methods for forming the same. Advantageously, the passive optical elements in displays may be used to cover for defective pixels in displays.

One general aspect includes a method of forming a display comprising a plurality of LEDs and a passive optical element. The method includes forming the passive optical element and attaching the passive optical element to a surface of two or more LEDs of the plurality of LEDs. The two or more LEDs comprise a first LED and a second LED. The passive optical element redistributes light emitted from the first LED to exit the display in a first and second region of the display. The first region of the display corresponds to the first LED, and the second region of the display corresponds to the second LED.

In some embodiments, forming the passive optical element comprises forming a first mirror and a second mirror. The first mirror is a partial mirror that transmits a portion of light emitted from the first LED to exit the display in the first region corresponding to the first LED and reflects a remaining portion of light emitted from the first LED towards the second mirror. The second mirror is a full mirror that reflects light from the first mirror to exit the display in the second region corresponding to the second LED. In some embodiments, the partial mirror is a half mirror that transmits about 50% of light emitted from the first LED and reflects about 50% of light emitted from the first LED. In some embodiments, the first LED and the second LED are adjacent LEDs of the display.

In some embodiments, the two or more LEDs further comprise a third LED. The passive optical element transmits light emitted from the third LED to exit the display in a region of the display corresponding to the third LED. In some embodiments, the third LED is between the first LED and the second LED.

In some embodiments, the two or more LEDs further comprise a third LED. The passive optical element redistributes light emitted from the third LED to exit the display in a third region and the second region of the display. The third region of the display corresponds to the third LED.

In some embodiments, forming the passive optical element comprises forming a first mirror, a second mirror, a third mirror, and a fourth mirror. The first mirror is a first partial mirror that transmits a portion of light emitted from the first LED to exit the display in the first region corresponding to the first LED and reflects a remaining portion of light emitted from the first LED towards the second mirror. The second mirror is a first full mirror that reflects light from the first mirror to exit the second region of the display corresponding to the second LED. The third mirror is a second partial mirror that transmits a portion of light emitted from the third LED to exit the display in the third region corresponding to the third LED and reflects a remaining portion of light emitted from the third LED towards the fourth mirror. The fourth mirror is a second full mirror that reflects light from the third mirror to exit the second region of the display corresponding to the second LED.

In some embodiments, the first partial mirror transmits about 75% of light emitted from the first LED and reflects about 25% of light emitted from the first LED. The second partial mirror transmits about 75% of light emitted from the third LED and reflects about 25% of light emitted from the third LED.

In some embodiments, the two or more LEDs further comprise a fourth LED and a fifth LED. The passive optical element redistributes light emitted from the fourth LED to exit the display in a fourth region and the second region of the display, the fourth region of the display corresponding to the fourth LED. The passive optical element redistributes light emitted from the fifth LED to exit the display in a fifth region and the second region of the display, the fifth region of the display corresponding to the fifth LED.

In some embodiments, the two or more LEDs further comprise a third LED. The passive optical element comprises a brightness enhancement film in a portion of the passive optical element overlapping the third LED when the display is viewed from top down or bottom up. The passive optical element enhances light emitted from the third LED to exit the display in a region of the display corresponding to the third LED.

In some embodiments, forming the first mirror and the second mirror comprises depositing a first reflective film on a first portion of a first dielectric layer and a second reflective film on a second portion of the first dielectric layer. Forming the passive optical element further comprises depositing a second dielectric layer on the first reflective film, the second reflective film, and a third portion of the first dielectric layer; and polishing the second dielectric layer.

In some embodiments, forming the passive optical element further comprises attaching the second dielectric layer to a substrate, and forming a third dielectric layer on a surface of the first dielectric layer that is opposite another surface of the first dielectric layer in contact with the first and second reflective films.

In some embodiments, attaching the passive optical element to the surface of two or more LEDs comprises bonding a surface of the substrate to the surface of the two or more LEDs.

In some embodiments, the two or more LEDs further comprise a third LED. The passive optical element comprises a plurality of optical blocks comprising a splitter block, a waveguide block, and a reflector block. Attaching the passive optical element comprises attaching the splitter block to the surface of the first LED, attaching the reflector block to the surface of the second LED, and attaching the waveguide block to the surface of the third LED. The splitter block transmits light emitted from the first LED to exit the display in the first region corresponding to the first LED and reflects a remaining portion of light emitted from the first LED to the waveguide block. The waveguide block transmits light from the splitter block to the reflector block. The reflector block reflects the light from the waveguide block to exit the display in the second region corresponding to the second LED. The waveguide block receives light from the third LED and transmits the light from the third LED to exit the display in a third region corresponding to the third LED.

In some embodiments, the passive optical element comprises a plurality of optical blocks comprising a splitter block and a reflector block. Attaching the passive optical element comprises attaching the splitter block to a surface of the first LED, and attaching the reflector block to a surface of the second LED. The splitter block transmits a portion light emitted from the first LED to exit the display in the first region corresponding to the first LED and reflects a remaining portion of light emitted from the first LED to the reflector block. The reflector block reflects the light from the splitter block to exit the display in the second region corresponding to the second LED.

In some embodiments, the passive optical element further comprises a collimating lens. The method further comprises, prior to attaching the splitter block to the surface of the first LED. attaching the collimating lens to the splitter block. The splitter block reflects the remaining portion of light from the first LED to the collimating lens. The collimating lens collimates light exiting the splitter block to the reflector block. In some embodiments, the first LED and the second LED are separated by a third LED of the plurality of LEDs.

In some embodiments, forming the first mirror comprises forming the first mirror disposed in a first layer stack. Forming the second mirror comprises forming the second mirror disposed in a second layer stack. Forming the passive optical element comprises bonding the first layer stack and the second layer stack.

Another general aspect includes a display (e.g., display device). Generally, the display includes a plurality of LEDs and a passive optical element attached to a surface of two or more LEDs of the plurality of LEDs.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1-3 schematically illustrates examples of passive optical elements and use in a display device, according to some embodiments;

FIG. 4 schematically illustrates an example of a pixel configuration surrounding a defective pixel, according to some embodiments;

FIG. 5 schematically illustrates an example of a passive optical element and use in a display device, according to some embodiments;

FIGS. 6A-6B schematically illustrates aspects of a method of forming a passive optical element, according to some embodiments;

FIGS. 7-8 schematically illustrates examples of passive optical elements and use in a display device, according to some embodiments;

FIG. 9A schematically illustrates a cross section example of a three component passive optical element and use in a display device, according to some embodiments;

FIGS. 9B-9C schematically illustrates examples of a top view of a three component passive optical element in a display device, according to some embodiments;

FIG. 10 schematically illustrates a cross section example of a two component passive optical element and use in a display device, according to some embodiments;

FIGS. 11A-11D schematically illustrates aspects of a method of forming a two-layer passive optical element, according to some embodiments;

FIG. 11E schematically illustrates an example of use of the two-layer passive optical element in a display device, according to some embodiments;

FIGS. 12A-12B schematically illustrate example layers of a two-layer passive optical element, according to some embodiments;

FIGS. 12C-12D schematically illustrate aspects of a method of forming a two-layer passive optical element, according to some embodiments;

FIG. 12E schematically illustrates an example of use of a two-layer passive optical element in a display device, according to some embodiments; and

FIGS. 13A-13B schematically illustrate direct bonding, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein provide for passive optical elements in displays and methods for forming the same. The passive optical elements in displays may be used to cover for defective pixels in displays by directing light from one or more working pixels of the display to cover an area of the display corresponding to the defective pixel.

A display may be an LED display (e.g., a micro-LED display). A micro-LED display may have pixels with its sides less than about 100 microns, less than about 50 microns, or less than about 5 microns in size. The pixel size may depend on application. For example, an extended reality (XR) display (e.g., virtual reality (VR), augmented reality (AR), or mixed reality (MR) display) may have a pixel size of about 5 microns or under, a watch may have a display with pixel size of less than about 30-50 microns, a mobile phone may have a display with pixel size of about 50-70 microns, televisions may have a display with a pixel size of about 500-1000 microns, etc. A pixel may include multiple sub-pixels or LEDs. For example, a pixel may include three sub-pixels comprising a red LED, a blue LED, and a green LED. As another example, a pixel may include four sub-pixels comprising a red LED, a blue LED, and two green LEDs. In some embodiments, a pixel may comprise any suitable number of sub-pixels or LEDs (e.g., one, two, three or more LEDs).

An LED display may comprise millions of LEDs. Different colored LEDs may be fabricated on different wafers (e.g., red LED wafer, green LED wafer, blue LED wafer), singulated (e.g., diced) into individual LEDs (e.g., red LEDs, green LEDs, and blue LEDs), and then transferred (e.g., picked and placed, bonded) onto a display backplane (e.g., transistor matrix, silicon or TFT backplane) to form a display. Pick and place tools may perform transfers in which LEDs of one color (e.g., red, green, or blue LEDs) are collected and bonded to a display backplane. There may be a large number of LEDs to transfer (e.g., millions of LEDs) so each LEDs may not be tested prior to transfer, and the testing may be performed after the LEDs are transferred. One or more LEDs may be defective after transfer. For example, the LED may emit light in a wrong color spectrum (e.g., outside a specified range of wavelengths), or the LED may not emit enough light (e.g., lower efficiency than other LEDs of a same color) or may not emit any light. In some examples, the LED may have a problem in the connection from the display backplane to the LED, a faulty location on the display (e.g., defect in display backplane), or a problem with the fabrication process in certain area of the LED wafer (e.g., LED picked from a certain area that is not working). Yields for LEDs may be high (e.g., more than about 99%, or more than about 99.5%). However, even with high yields, moving millions of LEDs may result in hundreds or thousands of defective pixels.

Replacing the defective LEDs may increase in difficulty as pixel sizes decreases. For LEDs down to about 0.5 mm in size, it may be possible to remove an LED and replace it with another LED (e.g., by desoldering and soldering an LED). However, the process of removing and replacing an LED is time consuming. To fix a defective LED, some pixels may have redundancy pads, and new micro-LEDs may be mounted at open locations. As pixel sizes go down in size (e.g., pixel sizes less than about 35 microns, or less than about 30 microns, or less than about 5 microns), hybrid bonding may be used instead of soldering, and reworking the LED at such dimensions may not be possible or practical.

Embodiments herein provide for passive optical elements in displays that may be used to cover for defective pixels in displays by directing light from one or more working pixels of the display to cover an area of the display corresponding to the defective pixel. In some embodiments, a defective pixel may be electrically disconnected, and light may be directed from another pixel. In some embodiments, a defective LED may be electrically disconnected, and light may be directed from another LED (e.g., adjacent LED(s), non-adjacent LED(s), and/or adjacent or non-adjacent LED(s) surrounding the defective LED) to exit out a region of the display corresponding to the defective LED. One or more passive optical elements may attached to the display using an adhesive or via direct bonding.

As described below, semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200°° C., >250°° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

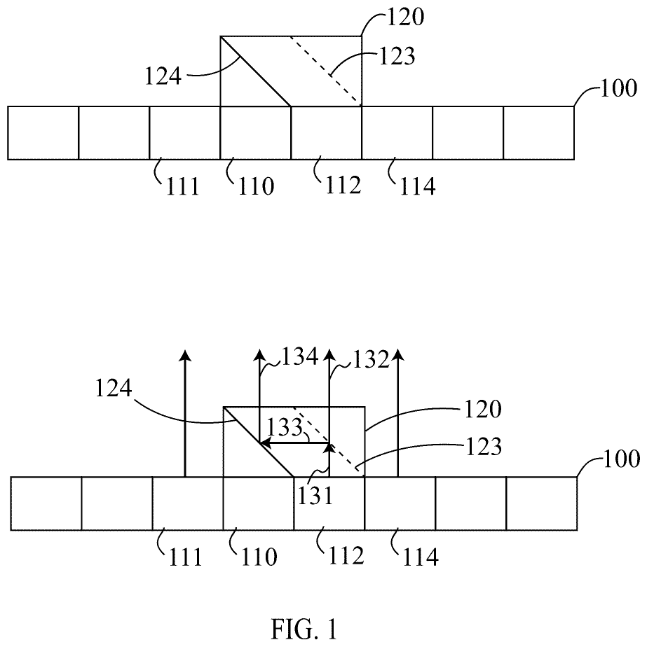

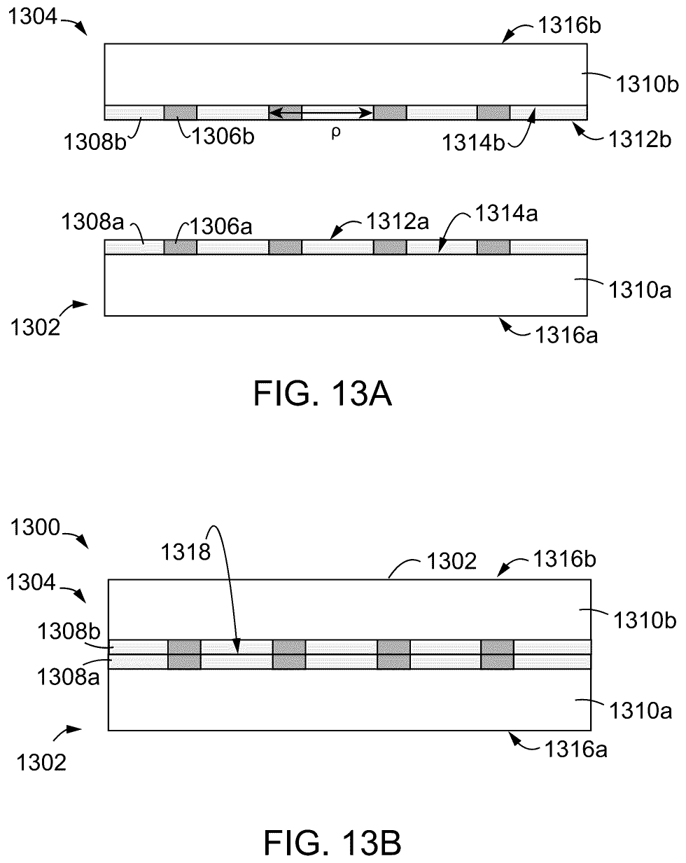

FIGS. 1-5 and 8, 9A-9C, 10, 11E and 12E schematically illustrate various embodiments of a display. The display may comprise LEDs. In some embodiments, the display may be a microLED display. For example, the LEDs (e.g., LED 110-114, 210-214, 310-314, 410-418, 510-517, 710, 712, 714, 810, 812, 814, 910, 912, 914, 1010, 1012, 1014, 1110-1113, 1115, 1210-1213, 1215) may be microLEDs, with sizes equal to or less than about 100 microns, 50 microns, or 5 microns. FIGS. 13A-13B illustrate a direct bonding method for bonding substrates. The techniques described in FIGS. 13A-13B may be applied for bonding any suitable substrates (e.g., passive optical elements to displays). Even though FIGS. 13A-13B may show an example of hybrid bonding, it can be understood that the techniques described may also be applied to examples of direct bonding.

In some embodiments, the display (e.g., any suitable display described throughout the present disclosure) may be an LED display and comprise LEDs (e.g., LED 110-114, 210-214, 310-314, 410-418, 510-517, 710, 712, 714, 810, 812, 814, 910, 912, 914, 1010, 1012, 1014, 1110-1113, 1115, 1210-1213, 1215) greater than about 500 microns in size, or greater than about 100 microns in size. In some embodiments, the methods, systems, and apparatus (e.g., display) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

FIG. 1 schematically illustrates an example of a passive optical element 120 and use in a display device, according to some embodiments. For example, FIG. 1 shows an example of a passive optical element 120 redistributing light emitted from an LED 112 to cover regions of the display 100 corresponding to the LED 112 and an adjacent LED 110 that may be defective. The display 100 comprises a plurality of LEDs (e.g., LED 110, LED 111, LED 112, and LED 114) and a passive optical element 120. The passive optical element 120 covers two adjacent LEDs (e.g., a first LED 112 and second LED 110) of the display 100 when viewed from bottom up or top down. The passive optical element 120 redistributes light 131 emitted from the first LED 112 to exit the display 100 in a first and second region of the display. The first region of the display 100 corresponds to the first LED 112, and the second region of the display 100 corresponds to the second LED 110. For example, a portion of light emitted from a working LED (e.g., first LED 112) may be redirected to emit in a region corresponding to a defective LED (e.g., second LED 110), and a viewer may not notice a defective LED on the display 100. In some embodiments, a passive optical element 120 may be directly bonded to the display 100 without using an adhesive. In some embodiments, a passive optical element 120 may be mounted to the display 100 using a transparent adhesive.

The passive optical element 120 comprises a first mirror 123 and a second mirror 124. The first mirror may be a semi-transparent element. A first mirror 123 may be a part of a beam splitter element. The second mirror may be a reflective element. The first mirror 123 and the second mirror 124 may be embedded in a dielectric material (e.g., oxide). In some embodiments, a passive optical element 120 may comprise glass or any other suitable optically transparent substrate. The thickness of the passive optical element 120 may be less than about 25 microns, or less than about 20 microns, or less than about 15 microns, or less than about 10 microns thick.

In some embodiments, the first mirror 123 is a partial mirror (e.g., a partially reflecting (or partially transmitting) mirror). In some embodiments, the first mirror 123 can be a beam-splitting element or layer. The first mirror 123 transmits a portion of light 132 emitted from the first LED 112 to exit the display in the first region corresponding to the first LED 112. The first mirror 123 reflects a remaining portion of light 133 emitted from the first LED 112 towards the second mirror 124. In some embodiments, the second mirror 124 is a full mirror that reflects light 134 from the first mirror 123 to exit the display in the second region corresponding to the second LED 110.

In some embodiments, the partial mirror is a half mirror that transmits about 50% of light emitted from the first LED 112 and reflects about 50% of light emitted from the first LED 112. In some embodiments, the partial mirror may transmit any suitable amount of light and reflect any suitable amount of light emitted from the first LED 112 (e.g., above or below 50%, such as transmit about 65% and reflect about 35%, transmit about 60% and reflect about 40%, transmit about 55% and reflect about 45%; transmit about 45% and reflect about 55%, transmit about 40% and reflect about 60%, transmit about 35% and reflect about 65%, etc.).

In some embodiments, the partial mirror may be a type of beam splitter. For example, the partial mirror may be a polarized beam splitter (e.g., to transmit light of one polarization, reflect light of another polarization).

In some embodiments, the first mirror 123 may be a dichroic mirror. For example, the first mirror may transmit light of wavelengths in a first range of wavelengths and reflect light of wavelengths in another range of wavelengths (e.g., red, green, blue, red/green, green/blue, red/blue light). In some embodiments, the first mirror 123 may be a full mirror instead of a partial mirror.

Although FIG. 1 shows an example where light from an LED is used to cover for an adjacent LED that may be defective (e.g., light from LED 112 is used to cover for adjacent LED 110 that may be defective), other embodiments may utilize light from a LED to cover for a non-adjacent LED that may be defective (e.g., example shown in FIG. 2). A defective LED may not emit any light, may emit light less than its peak brightness, may emit light of different wavelength or may exhibit any other defect.

FIG. 2 schematically illustrates an example of passive optical element 220 and use in a display device, according to some embodiments. For example, FIG. 2 shows a passive optical element 220 that redistributes light from an LED 214 to cover regions of the display 200 corresponding to the LED 214 and a non-adjacent LED 210 that may be defective.

FIG. 2 shows the display 200 comprising a plurality of LEDs (e.g., LED 210, LED 211, LED 212, and LED 214) and a passive optical element 220. In some embodiments, the passive optical element 220 may be similar to passive optical element 120 of FIG. 1, except the passive optical element 220 may include a pass through portion (e.g., enabling light from an underlying LED to pass through the passive optical element) and the passive optical element 220 is larger in size than the passive optical element 120 of FIG. 1 (e.g., covers three instead of two LEDs). The passive optical element 220 covers three LEDs 210, 212, and 214 (e.g., a first LED 214, second LED 210, and a third LED 212) of a display 200 when viewed from bottom up or top down. The third LED 212 may be between the first LED 214 and the second LED 210. The passive optical element 220 transmits light emitted from the third LED 212 to exit the display 200 in a region of the display corresponding to the third LED 212. In some embodiments, a passive optical element 220 may be directly bonded to the display 200 without using an adhesive. In some embodiments, a passive optical element 220 may be mounted to the display 200 using a transparent adhesive.

The passive optical element 220 redistributes light 231 emitted from the first LED 214 to exit the display 200 in a first and second region of the display. The first region of the display 200 corresponds to the first LED 214, and the second region of the display 200 corresponds to the second LED 210. For example, a portion of light emitted from a working LED (e.g., first LED 214) may be redirected to emit in a region corresponding to a defective LED (e.g., second LED 210), and a viewer may not notice a defective LED on the display 200.

The passive optical element 220 comprises a first mirror 223 and a second mirror 224. The first mirror 223 is a partial mirror. The first mirror 223 transmits a portion of light 232 emitted from the first LED 214 to exit the display 200 in the first region corresponding to the first LED 214. The first mirror 223 reflects a remaining portion of light 233 emitted from the first LED 214 towards the second mirror 124. The second mirror 224 is a full mirror that reflects light 234 from the first mirror 223 to exit the display 200 in the second region corresponding to the second LED 210.

In some embodiments, the first mirror 223 and the second mirror 224 of FIG. 2 are similar to the first mirror 123 and second mirror 124 of FIG. 1, respectively. In some embodiments, the passive optical element 220 of FIG. 2 is similar to the passive optical element 120 of FIG. 1 except that a spacing between the first mirror 223 and second mirror 224 of FIG. 2 is larger than a spacing between the first mirror 123 and second mirror 124 of FIG. 1. For example, the size of passive optical element 220 of FIG. 2 is larger than passive optical element 120 of FIG. 1. Although FIG. 2 shows first mirror 223 and second mirror 224 spaced apart by a distance corresponding to a single pixel pitch, the distance may correspond to any suitable number of pixel pitch (e.g., one, two, three or more times the pixel pitch).

Although FIG. 1 and FIG. 2 show examples where light from a single LED is used to cover for an LED that may be defective, other embodiments may utilize light from multiple LED to cover for an LED that may be defective (e.g., example shown in FIG. 3). In some embodiments, a passive optical element formed to utilize light from multiple LEDs may be larger in size than a passive optical element formed utilize light from a single LED. By increasing a number of pixels that light is collected from to cover for the defective pixel, an intensity difference between working pixels and defective pixels may be decreased. For example, using a single LED to compensate for a defective LED (e.g., sharing about 50% of emitted light to defective LED) may result in an unshared LED corresponding to about 100% emitted light, and shared LED and defective LED corresponding to about 50% emitted light in their respective regions of the display. For example, using two LEDs to compensate for a defective LED (sharing about 25% of emitted light) may result in an unshared LED corresponding to about 100% emitted light, and shared LED corresponding to about 75% of emitted light, and defective LED corresponding to about 50% of emitted light. As another example, using three LEDs to compensate for a defective LED (sharing about 25% of emitted light) may result in an unshared LED corresponding to about 100% emitted light, and shared LED and defective LED corresponding to about 75% of emitted light in their respective regions of the display.

FIG. 3 schematically illustrates an example of passive optical element and use in a display device, according to some embodiments. FIG. 3 shows a passive optical element 320 that redistributes light from multiple LEDs to cover regions of the display 300 corresponding to the respective LEDs (e.g., LED 311 and LED 312) and an adjacent LED (e.g., LED 310) that may be defective.

FIG. 3 shows the display 300 comprising a plurality of LEDs (e.g., LED 310, LED 311, LED 312, LED 313, and LED 314) and a passive optical element 320. The passive optical element 320 covers three LEDs 310, 311, and 312 (e.g., a first LED 312, second LED 310, and a third LED 311) of a display 300 when viewed from bottom up or top down. The second LED 310 may be between the first LED 314 and the third LED 311. The passive optical element 320 redistributes light 341 emitted from the third LED 311 to exit the display 300 in a third region and the second region of the display, the second region of the display 300 corresponding to the second LED 310 and the third region of the display 300 corresponding to the third LED 311.

The passive optical element 320 redistributes light 331 emitted from the first LED 314 to exit the display 300 in a first and second region of the display. The first region of the display 300 corresponds to the first LED 314, and the second region of the display 300 corresponds to the second LED 310. The passive optical element 320 redistributes light 341 emitted from the third LED 311 to exit the display 300 in a third and second region of the display. The third region of the display 300 corresponds to the third LED 311. For example, a portion of light emitted from working LEDs (e.g., first LED 314 and third LED 311) may be redirected to emit in a region corresponding to a defective LED (e.g., second LED 310), and a viewer may not notice a defective LED on the display 300. In some embodiments, a passive optical element 320 may be directly bonded to the display 300 without using an adhesive. In some embodiments, a passive optical element 320 may be mounted to the display 300 using a transparent adhesive.

The passive optical element 320 comprises a first mirror 323, a second mirror 324, a third mirror 325 and a fourth mirror 326. The first mirror 323, the second mirror 324, third mirror 325, and fourth mirror 326 may be embedded in a dielectric material (e.g., oxide). The thickness of the passive optical element 320 may be less than about 25 microns, or less than about 20 microns, or less than about 15 microns, or less than about 10 microns thick. The first mirror 323 is a first partial mirror. The first mirror 323 transmits a portion of light 332 emitted from the first LED 314 (e.g., about 75%) to exit the display 300 in the first region corresponding to the first LED 314. The first mirror 323 reflects a remaining portion of light 333 emitted from the first LED 314 (e.g., about 25%) towards the second mirror 324. The second mirror 324 is a first full mirror that reflects light 334 from the first mirror 323 to exit the display 300 in the second region corresponding to the second LED 310. The third mirror 325 is a second partial mirror. The third mirror 325 transmits a portion of light 342 emitted from the third LED 311 (e.g., about 75%) to exit the display 300 in the third region corresponding to the third LED 311. The third mirror 325 reflects a remaining portion of light 343 emitted from the third LED 313 (e.g., about 25%) towards the fourth mirror 326. The fourth mirror 326 is a second full mirror. The fourth mirror 326 reflects light 344 from the third mirror 325 to exit the second region of the display 300 corresponding to the second LED 310.

In this way, the light exiting a region of the display 300 corresponding to a defective LED (e.g., second LED 310) may correspond to about 50% light emitted from an LED (e.g., about 25% light emitted from LED 311 and about 25% of light emitted from LED 312), light exiting a portion of the display 300 corresponding to the LED 311 may correspond to about 75% of light emitted from an LED (e.g., about 75% of light emitted from LED 311), and light exiting a portion of the display 300 corresponding to the LED 312 may correspond to about 75% of light emitted from an LED (e.g., about 75% of light emitted from LED 312).

Any suitable portion of light may be transmitted and reflected by first mirror 323 and third mirror 325. In some embodiments, the portion of light transmitted and reflected may be selected based on minimizing or reducing a variation on the light transmitted in a region of the display across a plurality of LEDs (e.g., LED 310, LED 311, LED 312, LED 313, and LED 314). For example, LEDs 313 and 314 may emit about 100% of the light generated from the respective LEDs in a portion of the display 300 corresponding to the respective LEDs. The third LED 311 and the first LED 312 may emit a portion (e.g., about 75%) of the light generated from the respective LEDs in a portion of the display 300 corresponding to the respective LEDs. The second LED 310 may be defective, but a combined portion of light emitted from the third LED 311 and the first LED 312 (e.g., total of about 50%) may exit the display 300 in a portion of the display 300 corresponding to the second LED 310. In this way, the distribution of light may gradually change from about 100% to about 75% to about 50% (e.g., in regions of the display corresponding to LEDs 313 and/or 314 to LEDs 311 and/or 312 to LED 310).

In some embodiments, the first mirror 323 and third mirror 325 of FIG. 3 may be similar to the first mirror 123 of FIG. 1. In some embodiments, the second mirror 324 and fourth mirror 326 may be similar to the second mirror 124 of FIG. 1. In some embodiments, a passive optical element 320 may comprise glass or any other suitable optically transparent substrate. Although FIG. 3 shows first mirror 323 and second mirror 324 spaced apart by a distance corresponding to a single pixel pitch, the distance may correspond to any suitable number of pixel pitch (e.g., one, two, three or more times the pixel pitch). Although FIG. 3 shows second mirror 324 and second mirror 326 spaced apart by a distance corresponding to a single pixel pitch, the distance may correspond to any suitable number of pixel pitch (e.g., one, two, three or more times the pixel pitch). Although FIG. 3 shows an example where light is utilized from multiple LEDs on different sides of an LED that may be defective (e.g., LED 310 is between LED 311 and LED 312), in some embodiments light may be utilized from multiple LEDs on a same side of a defective LED to cover for the defective LED. For example, a passive optical element may be similar to passive optical element 320, except that it may or may not include third mirror 325 and fourth mirror 326, and is extended to include another mirror similar to the first mirror 323 in a region corresponding to LED 314. In some embodiments, the multiple LEDs may or may not be adjacent to the defective LED or to each other, and may be spaced apart (e.g., one, two, three or more times the pixel pitch).

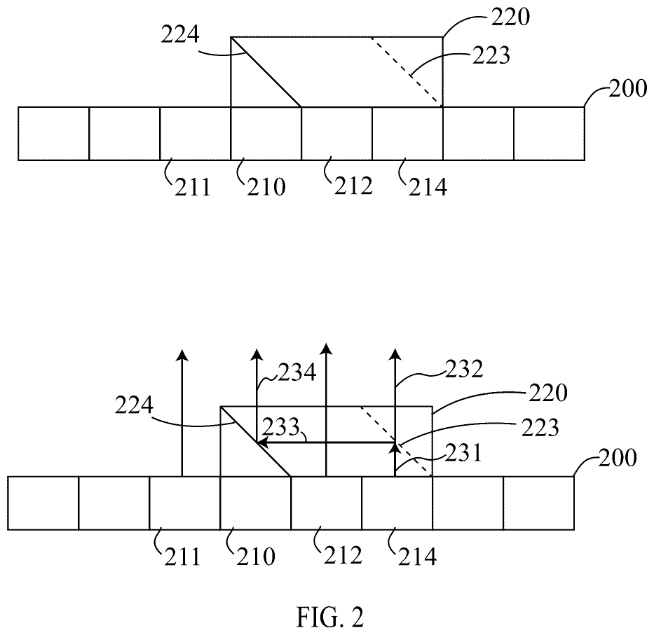

FIG. 4 schematically illustrates an example of a pixel configuration surrounding a defective pixel, according to some embodiments. For example, a defective pixel may be an LED 410. Any suitable number of LEDs may be used (one or more LEDs) to cover for a defective LED. In some embodiments, LEDs from different sides of the defective pixel are used (e.g., LEDs 411 and 412, or LEDs 413 and 414). In some embodiments, a passive optical element (e.g., passive optical element 320 of FIG. 3) may be used to cover LEDs 411, 410 and 412 of FIG. 4. For example, LEDs 411 and 412 are used to cover a defective LED 410. In some embodiments, a passive optical element (e.g., passive optical element 320 of FIG. 3) may be used to cover LEDs 413, 410 and 414 of FIG. 4. For example, LEDs 413 and 414 are used to cover a defective LED 410. In some embodiments, a passive optical element may comprise glass or any other suitable optically transparent substrate. In some embodiments, a passive optical element may be directly bonded to a display without using an adhesive. In some embodiments, a passive optical element may be mounted to the display using a transparent adhesive.

In some embodiments, LEDs 411, 412, 413, and 414 are used to cover a defective LED 410. For example, a display may comprise LEDs (e.g., first LED 412, second LED 410, third LED 411, fourth LED 413, and fifth LED 414). A passive optical element may be similar to a combination of two passive optical elements 320 of FIG. 3 that are orthogonal to each other. For example, a first component of the passive optical element (e.g., passive optical element 320 of FIG. 3) may be used to cover LEDs 411, 410, and 412 of FIG. 4 and a second component of the passive optical element (e.g., passive optical element 320 of FIG. 3) may be used to cover LEDs 413, 410, and 414 of FIG. 4. Where the first and second component of the passive optical element intersect in a region corresponding to LED 410, the four full mirrors (e.g., two pairs of mirrors 324 and 326 of FIG. 3) may each have a triangular shape (e.g., four triangular faces in a pyramid configuration).

The passive optical element redistributes light emitted from the first LED 414 to exit the display in a first and second region of the display. The first region of the display corresponds to the first LED 414, and the second region of the display corresponds to the second LED 410. The passive optical element redistributes light emitted from the third LED 411 to exit the display in a third and second region of the display. The third region of the display corresponds to the third LED 411. The passive optical element redistributes light emitted from the fourth LED 413 to exit the display in a fourth region and the second region of the display, the fourth region of the display corresponding to the fourth LED 413. The passive optical element redistributes light emitted from the fifth LED 414 to exit the display in a fifth region and the second region of the display, the fifth region of the display corresponding to the fifth LED 414. For example, a portion of light emitted from working LEDs (e.g., first LED 414, third LED 411, fourth LED 413, and fifth LED 414) may be redirected to emit in a region corresponding to a defective LED (e.g., second LED 410), and a viewer may not notice a defective LED on the display.

In some embodiments, LEDs 411, 412, 413, 414, 415, 416, 417 and 418 are used to cover a defective LED 410. In some embodiments, LEDs from a same side of the defective pixel are used to cover a defective LED 410. For example, LEDs 415, 413, and/or 416 are used to cover a defective LED 410. In some embodiments, LEDs 416, 412, and/or 417 are used to cover a defective LED 410. In some embodiments, LEDs 418, 414, and/or 417 are used to cover a defective LED 410. In some embodiments, LEDs 415, 411, and/or 418 are used to cover a defective LED 410.

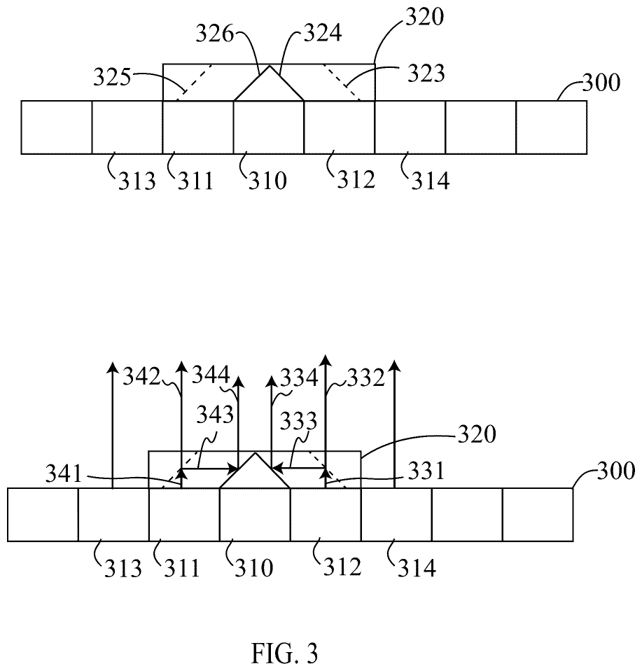

FIG. 5 schematically illustrates an example of a passive optical element 520 and use in a display device, according to some embodiments. The display 500 comprises a plurality of LEDs (e.g., first LED 512, second LED 510, third LED 511, and LEDs 513, 514, 515, 516 and 517). The passive optical element 520 redistributes light 531 emitted from the first LED 512 to exit the display 500 in a first and second region of the display. The passive optical element 520 comprises a brightness enhancement film 527 in a portion of the passive optical element 520 overlapping the third LED 511 when the display 500 is viewed from top down or bottom up. The brightness enhancement film may overlap another LED 513 when the display 500 is viewed from top down or bottom up. In some embodiments, the brightness enhancement film may be a film of prisms. The passive optical element 520 enhances light emitted from the third LED 511 to exit the display 500 in a region of the display corresponding to the third LED 511.

In some embodiments, the passive optical element 520 of FIG. 5 is similar to passive optical element 120 of FIG. 1 except that the passive optical element 520 includes a brightness enhancement film 527 and a pass-through region in portions of the passive optical element 520. The passive optical element 520 with the additional functions increases a size of the passive optical element 520 in comparison to passive optical element 120 (e.g., the passive optical element 520 has a larger area over passive optical element 120). An increase in size of the passive optical element may make it easier to manufacture, assemble, and handle. In some embodiments, a passive optical element 520 may be directly bonded to the display 500 without using an adhesive. In some embodiments, a passive optical element 520 may be mounted to the display 500 using a transparent adhesive. In some embodiments, the first mirror 523 of FIG. 3 is similar to the first mirror 123 of FIG. 1. In some embodiments, the second mirror 524 of FIG. 3 is similar to the second mirror 124 of FIG. 1. For example, the first mirror 523 transmits a portion of light 532 emitted from the first LED 512 to exit the display 500 in the first region corresponding to the first LED 512. The first mirror 523 reflects a remaining portion of light 533 emitted from the first LED 512 towards the second mirror 524. The second mirror 524 is a full mirror that reflects light 534 from the first mirror 523 to exit the display 500 in the second region corresponding to the second LED 510.

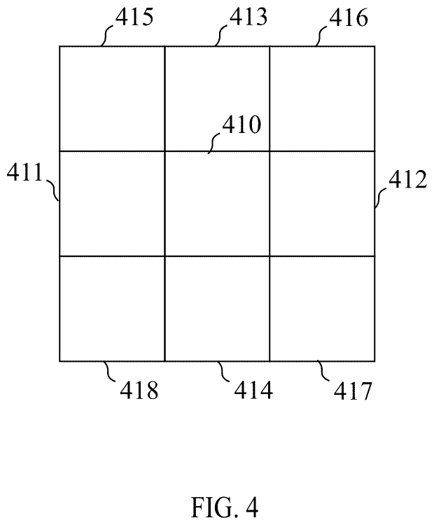

FIGS. 6A-6B schematically illustrates aspects of a method of forming a passive optical element, according to some embodiments. At block 10, openings may be etched in the first substrate 601. The substrate 601 may include openings in a first surface of the first substrate 601. A second surface of the first substrate is opposite the first surface of the first substrate. For example, the first substrate 601 may comprise a silicon substrate with openings on one surface of the silicon substrate. In some embodiments, openings may be formed in first substrate 601. For example, the openings may be etched in the silicon substrate. The first substrate 601 may be referred to as a temporary substrate.

At block 11, a first dielectric layer 602 is deposited on the first surface of the substrate 601 including the openings. For example, the first dielectric layer 602 may comprise an oxide material, and a layer of oxide material may be deposited on the first surface of the silicon substrate including the openings.

At block 12, a first mirror 623 and a second mirror 624 are formed. In some embodiments, the first mirror 623 and the second mirror 624 of FIG. 6A-6B are similar to the first mirror 223 and second mirror 224 of FIG. 2, respectively. First mirror 623 may be a partial mirror, and the second mirror 624 may be a full mirror. Forming the first mirror 623 may comprise depositing a first reflective film on a first portion of the dielectric layer 602. Forming the second mirror 624 may comprise depositing a second reflective film on a second portion of the first dielectric layer 602. In some embodiments, the first reflective film and the second reflective film may comprise different materials. In some embodiments, the first mirror 623 may be a half silvered mirror, and the second mirror 624 may be a full silvered mirror.

In some embodiments, the first mirror 623 and second mirror 624 may be formed by depositing and patterning a metal layer. For example, a metal layer (e.g., aluminum material, aluminum alloy material) may be patterned via lift-off. In some embodiments, the first mirror 623 and the second mirror 624 may be formed of different materials. In some embodiments, the first mirror 623 may be a dichroic mirror.

At block 13, a second dielectric layer 603 is deposited to encapsulate the first mirror 623 and the second mirror 624. For example, the second dielectric layer 603 is an oxide layer. The second dielectric layer 603 may be deposited on the first reflective film (e.g., the first mirror 623), the second reflective film (e.g., the second mirror 624), and the first dielectric layer 602. In some embodiments, the first dielectric layer 602 may comprise a same material as the second dielectric layer 603. For example, the first dielectric layer 602 and the second dielectric layer 603 may comprise an oxide material. The second dielectric layer 603 may be planarized. For example, the second dielectric layer 603 may be planarized using chemical mechanical polishing.

At block 14, the second dielectric layer 603 is bonded to a second substrate 604. For example, the second substrate 604 comprises a glass substrate. In some embodiments, the second substrate 604 may be a transparent substrate and may remain in a passive optical element that is formed. In some embodiments, the second substrate 604 may be later removed to form a passive optical element, and the second substrate may be referred to as a temporary substrate.

At block 15, the first substrate 601 is thinned. For example, the second surface of the first substrate 601 is thinned. The second surface of the first substrate 601 being opposite the first surface of the first substrate 601 comprising openings on the first surface. For example, a silicon substrate may be thinned.

At block 16, the first substrate 601 is removed. For example, a thinned silicon substrate may be selectively removed with a wet etch.

At block 17, a third dielectric layer 605 is deposited on the second dielectric layer 603. The third dielectric layer 605 may comprise a same material as the second dielectric layer 603 and first dielectric layer 602. For example, the third dielectric layer 605 comprises an oxide material. The third dielectric layer 605 may be chemically mechanically polished to planarize a surface of the third dielectric layer 605 and to form the passive optical element 620.

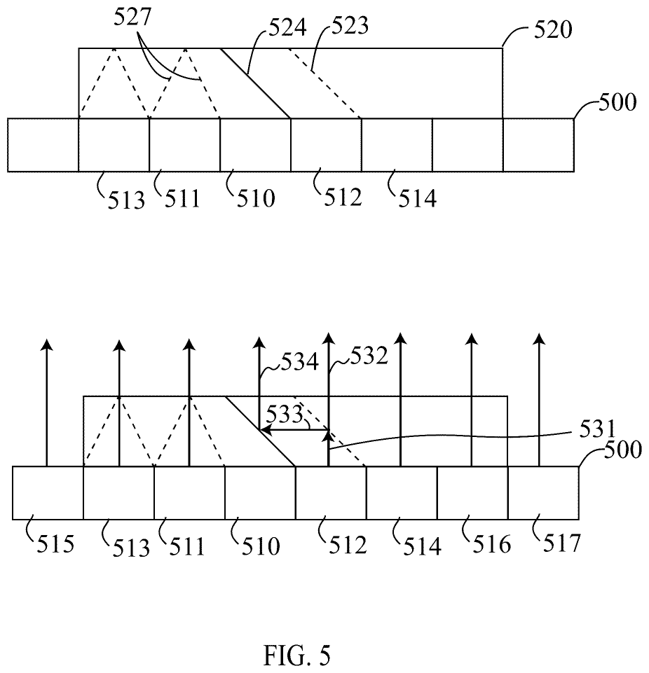

In some embodiments, the second substrate 604 remains in the passive optical element 620 (e.g., passive optical element 720 of FIG. 7). For example, the second substrate 604 may be a transparent substrate. In some embodiments, the substrate 604 is removed to form a passive optical element (e.g., passive optical element 820 of FIG. 8).

In some embodiments, the passive optical element 620 may be singulated. For example, although only one passive optical element 620 is shown as being formed in FIG. 6B, a plurality of passive optical elements may be formed and then singulated. The singulated passive optical element may be picked and placed over a defective pixel. In some embodiments, the passive optical element may be directly bonded to a display surface. In some embodiments, the passive optical element may be attached using adhesive (e.g., transparent adhesive). In some embodiments, the passive optical element may optically connect adjacent pixels or more distant pixels.

FIGS. 7-8 schematically illustrates examples of passive optical elements and use in a display device, according to some embodiments. For example, FIG. 7 shows a passive optical element 720 that is similar to the passive optical element 620 in FIG. 6B. For example, FIG. 8 shows a passive optical element 820 that is similar to the passive optical element 620 of FIG. 6B with the second substrate 604 removed.

FIG. 7 shows a display 700 comprising a plurality of LEDs (e.g., LED 710, LED 712, and LED 714). In some embodiments, the passive optical element 720 is the same as passive optical element 620 in FIG. 6B. For example, substrate 704, first dielectric layer 702, second dielectric layer 703, first mirror 723, second mirror 724, and third dielectric layer 705 of FIG. 7 corresponds to (e.g., is similar to or the same as) substrate 604, first dielectric layer 602, second dielectric layer 603, first mirror 623, second mirror 624, and third dielectric layer 605 of FIG. 6. Substrate 704 is a transparent substrate. For example, the transparent substrate may be glass. In some embodiments, the passive optical element 720 may be directly bonded to the display 700. For example, a surface of the transparent substrate of the passive optical element 720 may be directly bonded to a surface of the display 700. In some embodiments, the passive optical element 720 is attached to display 700 using adhesive (e.g., transparent adhesive).

The passive optical element 720 redistributes light emitted from a working pixel (e.g., first LED 714) to exit the display 700 in a first and second region of the display. The first region of the display 700 corresponds to the first LED 714, and the second region of the display 700 corresponds to the second LED 710. For example, a portion of light emitted from a working LED (e.g., first LED 714) may be redirected to emit in a region corresponding to a defective LED (e.g., second LED 710), and a viewer may not notice a defective LED on the display 700.

FIG. 8 shows a display 800 comprising a plurality of LEDs (e.g., LED 810, LED 812, and LED 814). In some embodiments, the passive optical element 820 is the same as passive optical element 620 in FIG. 6B except without the substrate 604. For example, first dielectric layer 802, second dielectric layer 803, first mirror 823, second mirror 824, and third dielectric layer 805 of FIG. 8 corresponds to (e.g., is similar to or the same as) substrate 604, first dielectric layer 602, second dielectric layer 603, first mirror 623, second mirror 624, and third dielectric layer 605 of FIG. 6. The passive optical element 820 redistributes light emitted from a working pixel (e.g., first LED 814) to exit the display 800 in a first and second region of the display. The first region of the display 800 corresponds to the first LED 814, and the second region of the display 800 corresponds to the second LED 810. For example, a portion of light emitted from a working LED (e.g., first LED 814) may be redirected to emit in a region corresponding to a defective LED (e.g., second LED 810), and a viewer may not notice a defective LED on the display 700.

In some embodiments, the passive optical element 820 may be directly bonded to the display 800. For example, a surface of the second dielectric layer 803 may be directly bonded to a surface of the display 800. In some embodiments, the passive optical element 820 is attached to display 800 using adhesive (e.g., transparent adhesive).

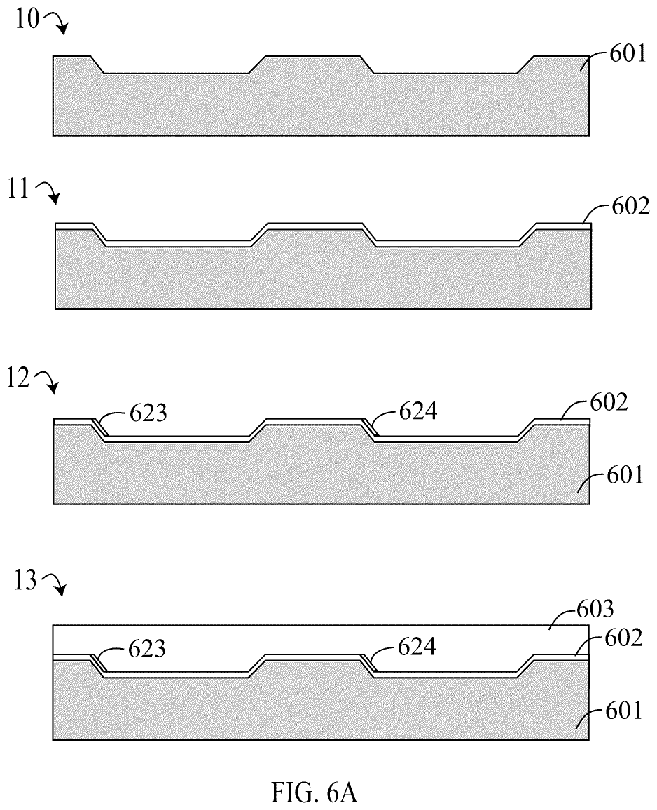

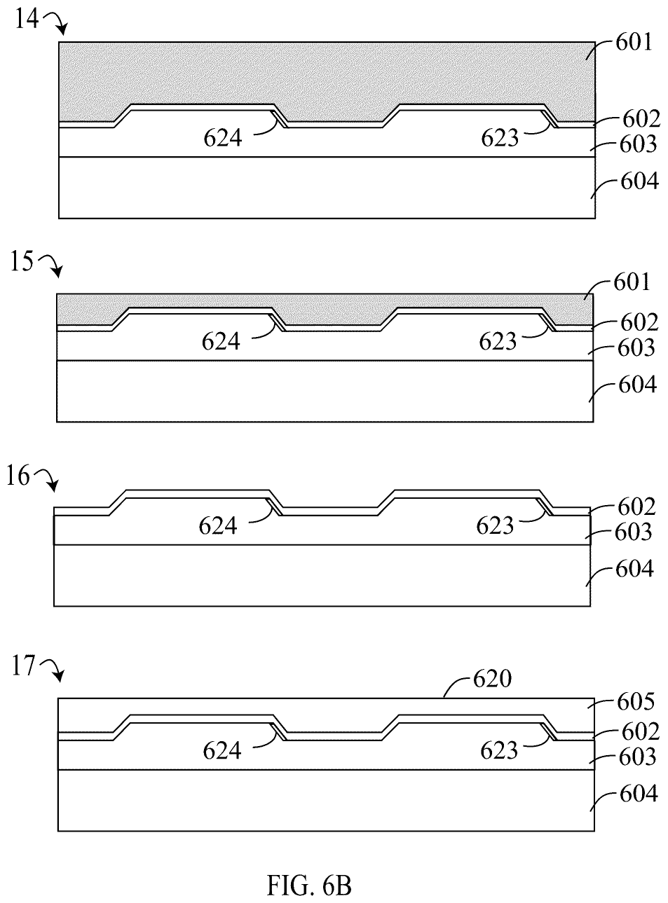

FIG. 9A schematically illustrates a cross section example of a three component passive optical element and use in a display device, according to some embodiments. The display 900 comprises a plurality of LEDs (e.g., first LED 914, second LED 910, and third LED 912) and a passive optical element. The passive optical element comprises a plurality of optical blocks comprising a splitter block 952a, a waveguide block 952a, and a reflector block 953a. Attaching the passive optical element comprises attaching the splitter block 951a to the surface of the first LED 914, attaching the reflector block 952a to the surface of the second LED 910, and attaching the waveguide block 952a to the surface of the third LED 912. The splitter block 951a may be attached to the display 900 (e.g., surface of a working LED) using direct bonding or transparent adhesive, and the reflector block 953a may be attached to the display 900 (e.g., surface of a defective LED) using direct bonding or adhesive. The waveguide block 952a may be attached to the display 900 (e.g., surface of a display region between the splitter block 951a and reflector block 953a) using direct bonding or transparent adhesive.

In some embodiments, the splitter block 951a and the reflector block 953a may be fabricated as generic components. For example, the splitter block 951a and the reflector block 953a may be fabricated to be a same size corresponding to the size of a pixel of the display 900. The waveguide block 952a may fabricated with different lengths. The waveguide block 952a may be positioned to match the defective pixel with the working pixel (e.g., source pixel). In some embodiments, an index matching gel may be deposited in the airgap between blocks.

The splitter block 951a transmits light emitted from the first LED 914 to exit the display 900 in the first region corresponding to the first LED 914 and reflects a remaining portion of light emitted from the first LED 914 to the waveguide block 952a. The waveguide block 952a transmits light from the splitter block 951a to the reflector block 953a. The reflector block 953a reflects the light from the waveguide block 952a to exit the display 900 in the second region corresponding to the second LED 910. The waveguide block 952a receives light from the third LED 912 and transmits the light from the third LED 912 to exit the display 900 in a third region corresponding to the third LED 912.

In some embodiments, the splitter block 951a comprises a partial mirror. For example, the splitter block 951a may comprise a first mirror corresponding to the first mirror 123 of FIG. 1. In some embodiments, the splitter block 951a may be a dichroic block. For example, the splitter block 951a may include a dichroic mirror. In some embodiments, the reflector block 953a comprises a full mirror. For example, the reflector block 953a may comprise a second mirror corresponding to the second mirror 124 of FIG. 1. In some embodiments, blocks may be referred to as chiplets (e.g., optical chiplets). In some embodiments, the splitter block 951a and the reflector block 953a may be tuned for a specific color (e.g., wavelength range). The coating for a mirror or a partial reflector may have improved performance for a smaller wavelength spectrum or range. For example, a splitter block 951a may be attached to a red LED and a reflector block 953a may be attached to a defective red LED, and the coating used for the splitter block 951a and reflector block 953a may be tuned for a wavelength range for red light. The splitter block 951a and reflector block 953a may have better performance for the smaller wavelength spectrum or range of red light.

FIGS. 9B-9C schematically illustrates examples of a top view of a three component passive optical element in a display device, according to some embodiments. FIG. 9B shows the three component passive optical element of FIG. 9A (e.g., splitter block 951a, waveguide block 952a, and reflector block 953a) aligned horizontally or vertically to the LEDs of the display device 900.

FIG. 9C shows a three component passive optical element that is aligned to LEDs (e.g., defective LED and working or source LED) that are not adjacent to each other. The splitter block 951b, waveguide block 952b, and reflector block 953b of FIG. 9C may be similar to the splitter block 951a, waveguide block 952a, and reflector block 953a of FIG. 9A, except one or more dimensions of the blocks may be different. For example, a length, width, and/or height of the blocks of FIG. 9C may be larger than a length, width, and/or height of the blocks of FIG. 9A. For example, a length of the waveguide block 952b may be longer than a length of the waveguide block 952a.

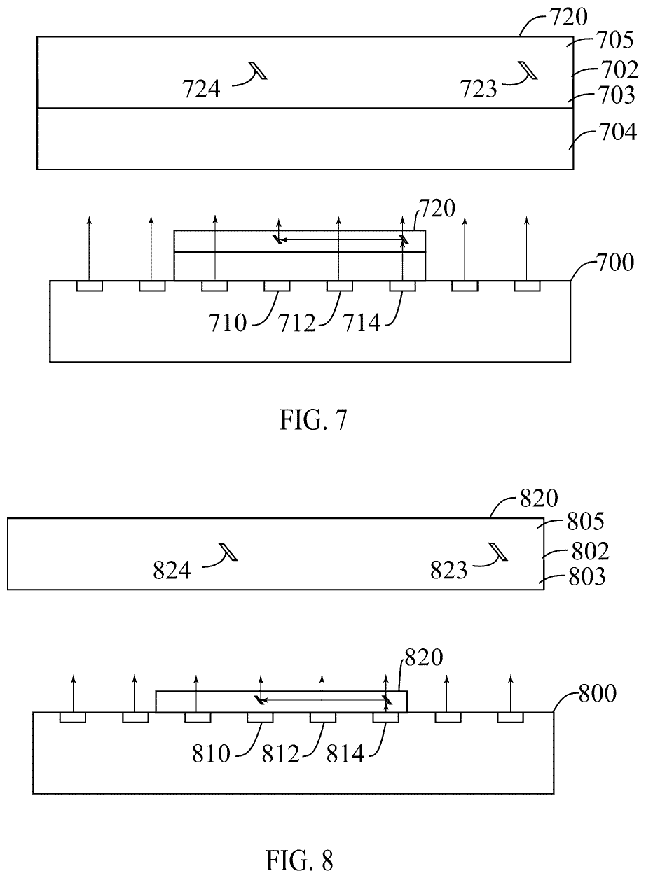

FIG. 10 schematically illustrates a cross section example of a two component passive optical element and use in a display device, according to some embodiments. In some embodiments, in which the distance of the pixels may be close so that dispersion may be limited, a separate waveguide block may not be used. The display device 1000 comprises a plurality of LEDs (e.g., first LED 1014, second LED 1010, and third LED 1012). The third LED 1012 is between the first LED 1014 and the second LED 1010. The second LED 1010 may be a defective LED. In some embodiments, the passive optical element comprises a plurality of optical blocks comprising a splitter block 1051 and a reflector block 1053. Attaching the passive optical element comprises attaching the splitter block 1051 to a surface of the first LED 1014 (e.g., using direct bonding or transparent adhesive), and attaching the reflector block to a surface of the second LED 1010 (e.g., using direct bonding or adhesive). The splitter block 1051 transmits a portion light emitted from the first LED 1014 to exit the display 1000 in the first region corresponding to the first LED 1014 and reflects a remaining portion of light emitted from the first LED 1014 to the reflector block 1053. The reflector block 1053 reflects the light from the splitter block 1051 to exit the display 1000 in the second region corresponding to the second LED 1010.

In some embodiments, the passive optical element further comprises a collimating lens 1054. A method may further comprise, prior to attaching the splitter block 1051 to the surface of the first LED 1014, attaching the collimating lens 1054 to the splitter block 1051. The splitter block 1051 reflects the remaining portion of light from the first LED 1014 to the collimating lens 1054. The collimating lens 1054 collimates light exiting the splitter block 1051 to the reflector block 1053.

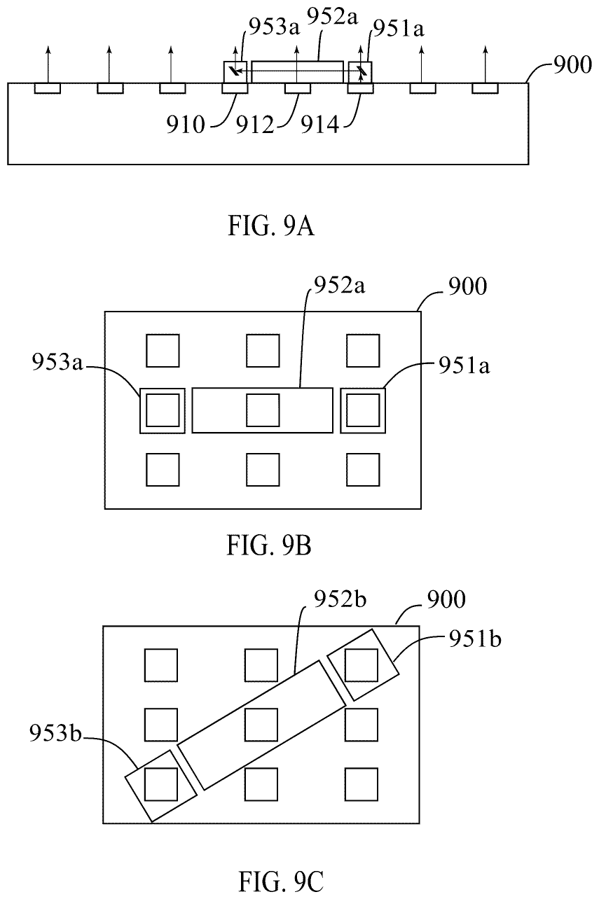

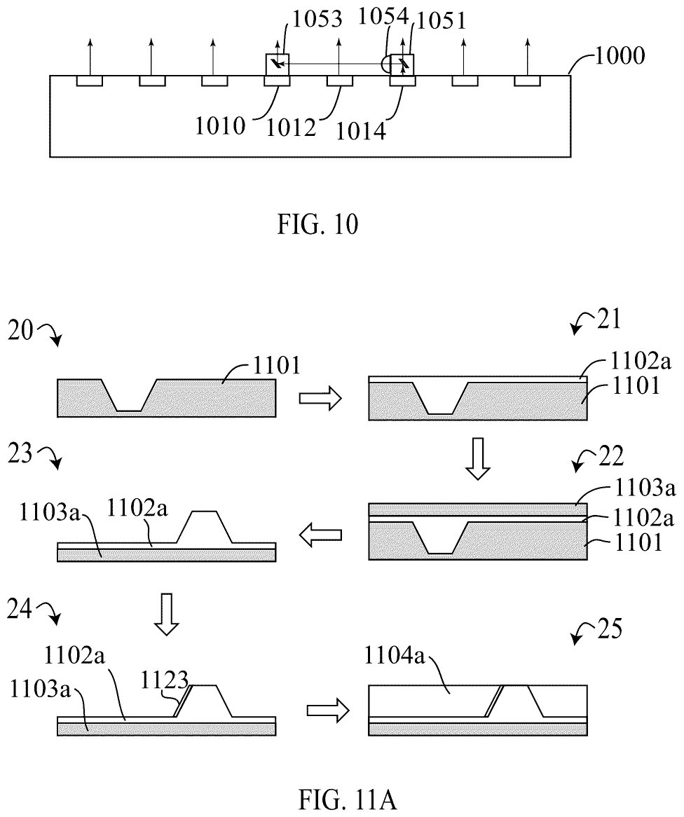

FIGS. 11A-11D schematically illustrates aspects of a method of forming a two-layer passive optical element, according to some embodiments. In some embodiments, forming the first mirror 1123 comprises forming the first mirror 1123 disposed in a first layer stack (e.g., a first dielectric layer 1102a and a second dielectric layer 1104a). In some embodiments, forming the second mirror 1124 comprises forming the second mirror 1124 disposed in a second layer stack (e.g., a first dielectric layer 1102b and a second dielectric layer 1104b). Forming the passive optical element comprises bonding the first layer stack and the second layer stack.

FIG. 11A illustrate forming the first mirror 1123 in the first layer stack. At block 20, a substrate 1101 includes an opening in a surface of the substrate 1101. In some embodiments, an opening in the substrate 1101 is formed. For example, the substrate 1101 may be silicon and the opening is etched in the silicon. At block 21, a first dielectric layer 1102a is deposited on the substrate 1101. For example, the first dielectric layer 1102a is deposited on a surface of the substrate 1101 including the opening. The first dielectric layer 1102a may be an oxide layer. In some embodiments, a polymer material may be used instead of a dielectric material (e.g., polymer layer instead of dielectric layer). At block 22, a second substrate 1103a is attached to the first dielectric layer 1102a (e.g., by direct bonding or using adhesive). For example, silicon may be bonded to an oxide layer. At block 23, the first substrate 1101 is removed. For example, silicon may be removed by etching. At block 24, a first mirror 1123 is formed. For example, a metal film may be formed on a portion of the first dielectric layer 1102a. At block 25, a second dielectric layer 1104a is deposited on the first dielectric layer 1102a and first mirror 1123. In some embodiments, a polymer material may be used instead of a dielectric material (e.g., polymer layer instead of dielectric layer).

FIG. 11B illustrate forming the second mirror 1124 in the second layer stack. At block 26, the second mirror 1124 is formed. For example, a metal film may be formed on a portion of the third dielectric layer 1102b. The third dielectric layer 1102b may be adjacent to a substrate 1103b. Substrate 1103b may be substantially similar to substrate 1103a of FIG. 11A. At block 27, a fourth dielectric layer 1104b is deposited on the second mirror 1124 and a portion of the third dielectric layer 1102b. The third dielectric layer 1102b and the fourth dielectric layer 1104b of FIG. 11B may be substantially similar to the first dielectric layer 1102a and the second dielectric layer 1104a of FIG. 11A.

FIG. 11C illustrates bonding of the first layer stack and the second layer stack. For example, the first layer stack and the second layer stack may be directly bonded. The first layer stack and the second layer stack may be attached using adhesive (e.g., transparent adhesive).

FIG. 11D illustrates removal of the substrate 1103b. In some embodiments, the dielectric layer 1102b may be attached to a surface of the display. Before or after, the dielectric layer 1102b is attached to a display, the substrate 1103a may be removed.

FIG. 11E schematically illustrates an example of use of the two-layer passive optical element 1120 in a display device, according to some embodiments. The display device includes a plurality of LEDs (e.g., first LED 1113, second LED 1110, third LED 1111, LED 1112, and LED 1115). In some embodiments, the first mirror 1123 is similar to first mirror 123 of FIG. 1, and the second mirror 1124 is similar to the second mirror 124 of FIG. 1. However, the angles of first mirror 1123 and second mirror 1124 may be different (e.g., not at about 45 degrees) than the angles of the first mirror 123 and second mirror 124 of FIG. 1 (e.g., about 45 degrees).

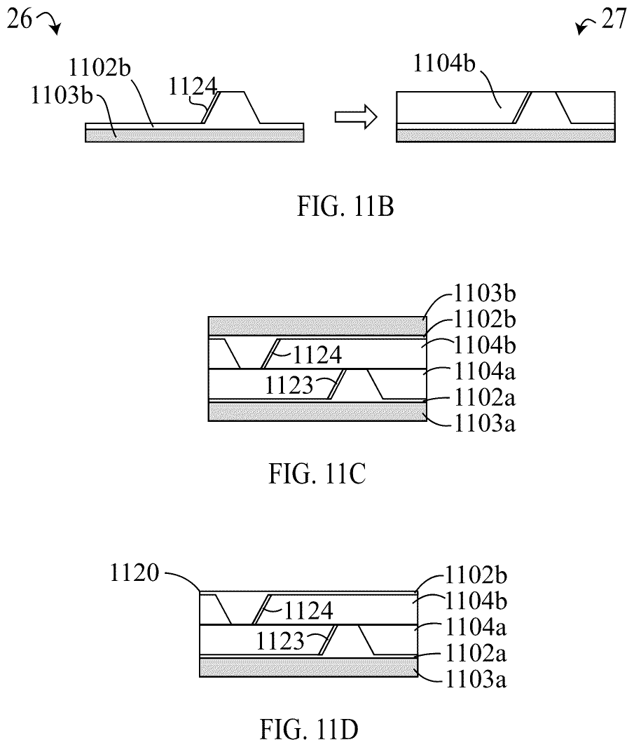

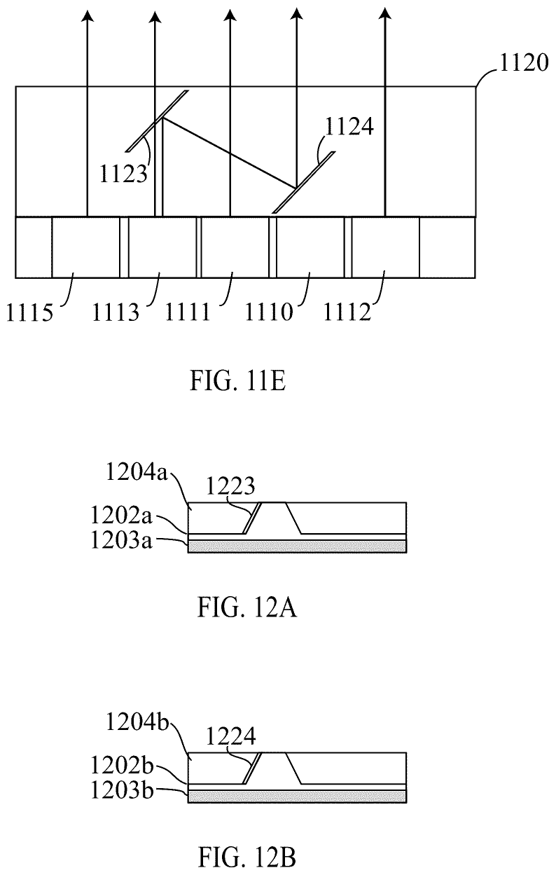

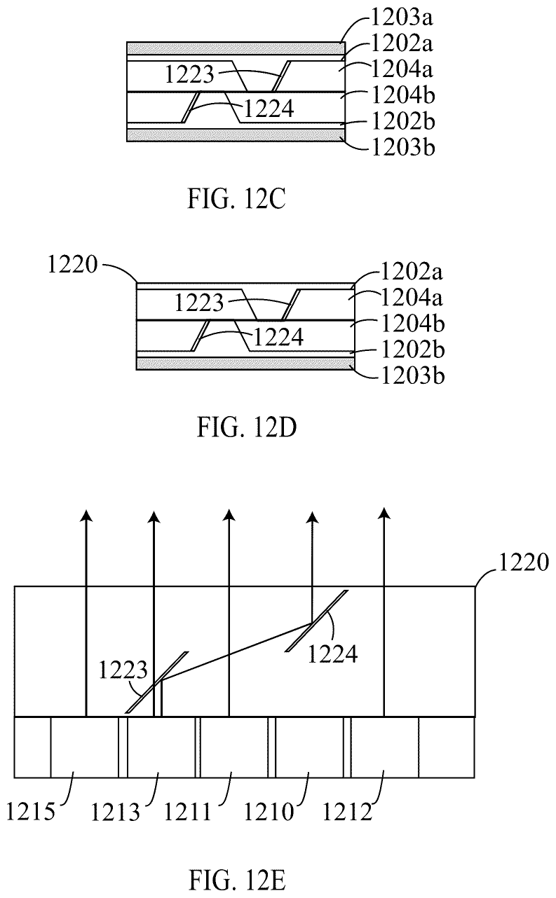

FIGS. 12A-12B schematically illustrate example layers of a two-layer passive optical element, according to some embodiments. In some embodiments, the first layer stack of FIG. 12A is similar to the first layer stack as shown in block 25 of FIG. 11A, except that the first mirror 1223 is a different position than the first mirror 1123 of FIG. 11A. For example, substrate 1203a, first dielectric layer 1202a, second dielectric layer 1204a, first mirror 1223 corresponds to or is similar to substrate 1103a, first dielectric layer 1102a, second dielectric layer 1104a, first mirror 1123, respectively, of FIG. 11A. In some embodiments, the second layer stack of FIG. 12B is similar to the second layer stack as shown in block 25 of FIG. 11B, except that the second mirror 1224 is a different position than the second mirror 1124 of FIG. 11B. For example, substrate 1203a, first dielectric layer 1202a, second dielectric layer 1204a, first mirror 1223 corresponds to or is similar to substrate 1103a, first dielectric layer 1102a, second dielectric layer 1104a, first mirror 1123, respectively, of FIG. 11A.

FIGS. 12C-12D schematically illustrate aspects of a method of forming a two-layer passive optical element, according to some embodiments. FIG. 12C illustrates bonding of the first layer stack and the second layer stack. For example, the first layer stack and the second layer stack may be directly bonded. The first layer stack and the second layer stack may be attached. FIG. 12D illustrates removal of the substrate 1203a. In some embodiments, the dielectric layer 1202a may be attached to a surface of the display. Before or after, the dielectric layer 1102a is attached to a display, the substrate 1203b may be removed.

FIG. 12E schematically illustrates an example of use of a two-layer passive optical element in a display device, according to some embodiments. The display device includes a plurality of LEDs (e.g., first LED 1213, second LED 1210, third LED 1211, LED 1212, and LED 1215). In some embodiments, the first mirror 1223 is similar to first mirror 123 of FIG. 1, and the second mirror 1224 is similar to the second mirror 124 of FIG. 1. However, the angles of first mirror 1123 and second mirror 1124 may be different (e.g., not at about 45 degrees) than the angles of the first mirror 123 and second mirror 124 of FIG. 1 (e.g., about 45 degrees). In the embodiment of FIG. 12, light reflected off of first mirror 1223 and second mirror 1224 diverges more than the light reflected off of the first mirror 1123 and the second mirror 1124 of the embodiment of FIG. 11.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1308a and/or 1308b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 13A and 13B schematically illustrate cross-sectional side views of first and second elements 1302, 1304 prior to and after, respectively, a process for forming a directly bonded structure. In some embodiments, the process can be implemented for a hybrid bonded structure in particular. In FIG. 1B, a bonded structure 1300 comprises the first and second elements 1302 and 1304 that are directly bonded to one another at a bond interface 1318 without an intervening adhesive. Conductive features 1306a of a first element 1302 may be electrically connected to corresponding conductive features 1306b of a second element 1304. In the illustrated hybrid bonded structure 1300, the conductive features 1306a are directly bonded to the corresponding conductive features 1306b without intervening solder or conductive adhesive.

The conductive features 1306a and 1306b of the illustrated embodiment are embedded in, and can be considered part of, a first bonding layer 1308a of the first element 1302 and a second bonding layer 1308b of the second element 1304, respectively. Field regions of the bonding layers 1308a, 1308b extend between and partially or fully surround the conductive features 1306a, 1306b. The bonding layers 1308a, 1308b can comprise layers of non-conductive materials suitable for direct bonding, as described above, and the field regions are directly bonded to one another without an adhesive. The non-conductive bonding layers 1308a, 1308b can be disposed on respective front sides 1314a, 1314b of base substrate portions 1310a, 1310b.

The first and second elements 1302, 1304 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1302, 1304, and back-end-of-line (BEOL) interconnect layers over such semiconductor portions. The bonding layers 1308a, 1308b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1310a, 1310b, and can electrically communicate with at least some of the conductive features 1306a, 1306b. Active devices and/or circuitry can be disposed at or near the front sides 1314a, 1314b of the base substrate portions 1310a, 1310b, and/or at or near opposite backsides 1316a, 1316b of the base substrate portions 1310a, 1310b. In other embodiments, the base substrate portions 1310a, 1310b may not include active circuitry, but may instead comprise dummy substrates, passive interposers, passive optical elements (e.g., glass substrates, gratings, lenses), etc. The bonding layers 1308a, 1308b are shown as being provided on the front sides of the elements, but similar bonding layers can be additionally or alternatively provided on the back sides of the elements.

In some embodiments, the base substrate portions 1310a, 1310b can have significantly different coefficients of thermal expansion (CTEs), and bonding elements that include such different based substrate portions can form a heterogenous bonded structure. The CTE difference between the base substrate portions 1310a and 1310b, and particularly between bulk semiconductor (typically single crystal) portions of the base substrate portions 1310a, 1310b, can be greater than 5 ppm/° C. or greater than 10 ppm/° C. For example, the CTE difference between the base substrate portions 1310a and 1310b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 1310a, 1310b can comprise optoelectronic single crystal materials, including perovskite materials, that are useful for optical piezoelectric or pyroelectric applications, and the other of the base substrate portions 1310a, 1310b comprises a more conventional substrate material. For example, one of the base substrate portions 1310a, 1310b comprises lithium tantalate (LiTaO₃) or lithium niobate (LiNbO₃), and the other one of the base substrate portions 1310a, 1310b comprises silicon (Si), quartz, fused silica glass, sapphire, or a glass. In other embodiments, one of the base substrate portions 1310a, 1310b comprises a III-V single semiconductor material, such as gallium arsenide (GaAs) or gallium nitride (GaN), and the other one of the base substrate portions 1310a, 1310b can comprise a non-III-V semiconductor material, such as silicon (Si), or can comprise other materials with similar CTE, such as quartz, fused silica glass, sapphire, or a glass. In still other embodiments, one of the base substrate portions 1310a, 1310b comprises a semiconductor material and the other of the base substrate portions 1310a, 1310b comprises a packaging material, such as a glass, organic or ceramic substrate.

In some arrangements, the first element 1302 can comprise a singulated element, such as a singulated integrated device die. In other arrangements, the first element 1302 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1304 can comprise a singulated element, such as a singulated integrated device die. In other arrangements, the second element 1304 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 1302, 1304 are shown, any suitable number of elements can be stacked in the bonded structure 1300. For example, a third element (not shown) can be stacked on the second element 1304, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1302. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1308a, 1308b, the bonding layers 1308a, 1308b can be prepared for direct bonding. Non-conductive bonding surfaces 1312a, 1312b at the upper or exterior surfaces of the bonding layers 1308a, 1308b can be prepared for direct bonding by polishing, for example, by chemical mechanical polishing (CMP). The roughness of the polished bonding surfaces 1312a, 1312b can be less than 30 Å rms. For example, the roughness of the bonding surfaces 1312a and 1312b can be in a range of about 0.1 Å rms to 15 Å rms, 0.5 Å rms to 10 Å rms, or 1 Å rms to 5 Å rms. Polishing can also be tuned to leave the conductive features 1306a, 1306b recessed relative to the field regions of the bonding layers 1308a, 1308b.

Preparation for direct bonding can also include cleaning and exposing one or both of the bonding surfaces 1312a, 1312b to a plasma and/or etchants to activate at least one of the surfaces 1312a, 1312b. In some embodiments, one or both of the surfaces 1312a, 1312b can be terminated with a species after activation or during activation (e.g., during the plasma and/or etch processes). Without being limited by theory, in some embodiments, the activation process can be performed to break chemical bonds at the bonding surface(s) 1312a, 1312b, and the termination process can provide additional chemical species at the bonding surface(s) 1312a, 1312b that alters the chemical bond and/or improves the bonding energy during direct bonding. In some embodiments, the activation and termination are provided in the same step, e.g., a plasma to activate and terminate the surface(s) 1312a, 1312b. In other embodiments, one or both of the bonding surfaces 1312a, 1312b can be terminated in a separate treatment to provide the additional species for direct bonding. In various embodiments, the terminating species can comprise nitrogen. For example, in some embodiments, the bonding surface(s) 1312a, 1312b can be exposed to a nitrogen-containing plasma. Other terminating species can be suitable for improving bonding energy, depending upon the materials of the bonding surfaces 1312a, 1312b. Further, in some embodiments, the bonding surface(s) 1312a, 1312b can be exposed to fluorine. For example, there may be one or multiple fluorine concentration peaks at or near a bond interface 1318 between the first and second elements 1302, 1304. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1300, the bond interface 1318 between two non-conductive materials (e.g., the bonding layers 1308a, 1308b) can comprise a very smooth interface with higher nitrogen (or other terminating species) content and/or fluorine concentration peaks at the bond interface 1318. In some embodiments, the nitrogen and/or fluorine concentration peaks may be detected using various types of inspection techniques, such as SIMS techniques. The polished bonding surfaces 1312a and 1312b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1308a and 1308b can be directly bonded to one another without an adhesive. In some embodiments, the elements 1302, 1304 are brought together at room temperature, without the need for application of a voltage, and without the need for application of external pressure or force beyond that used to initiate contact between the two elements 1302, 1304. Contact alone can cause direct bonding between the non-conductive surfaces of the bonding layers 1308a, 1308b (e.g., covalent dielectric bonding). Subsequent annealing of the bonded structure 1300 can cause the conductive features 1306a, 1306b to directly bond.

In some embodiments, prior to direct bonding, the conductive features 1306a, 1306b are recessed relative to the surrounding field regions, such that a total gap between opposing contacts after dielectric bonding and prior to anneal is less than 15 nm, or less than 10 nm. Because the recess depths for the conductive features 1306a and 1306b can vary across each element, due to process variation, the noted gap can represent a maximum or an average gap between corresponding conductive features 1306a, 1306b of two joined elements (prior to anneal). Upon annealing, the conductive features 1306a and 1306b can expand and contact one another to form a metal-to-metal direct bond.

During annealing, the conductive features 1306a, 1306b (e.g., metallic material) can expand while the direct bonds between surrounding non-conductive materials of the bonding layers 1308a, 1308b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1306a, 1306b can comprise discrete pads, contacts, electrodes, or traces at least partially embedded in the non-conductive field regions of the bonding layers 1308a, 1308b. In some embodiments, the conductive features 1306a, 1306b can comprise exposed contact surfaces of TSVs (e.g., through silicon vias).

As noted above, in some embodiments, in the elements 1302, 1304 of FIG. 1A prior to direct bonding, portions of the respective conductive features 1306a and 1306b can be recessed below the non-conductive bonding surfaces 1312a and 1312b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1306a, 1306b or to average depths of the recesses relative to local non-conductive field regions. Even for an individual conductive feature 1306a, 1306b, the vertical recess can vary across the feature, and so can be measured at or near the lateral middle or center of the cavity in which a given conductive feature 1306a, 1306b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 1306a, 1306b across the direct bond interface 1318 (e.g., small or fine pitches for regular arrays).

In some embodiments, a pitch p of the conductive features 1306a, 1306b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1306a and 1306b to one of the lateral dimensions (e.g., a diameter) of the bonding pad is less than is less than 20, or less than 10, or less than 5, or less than 3 and sometimes desirably less than 2. In various embodiments, the conductive features 1306a and 1306b and/or traces can comprise copper or copper alloys, although other metals may be suitable, such as nickel, aluminum, or alloys thereof. The conductive features disclosed herein, such as the conductive features 1306a and 1306b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1302, 1304, as shown, the orientations of one or more conductive features 1306a, 1306b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1306b in the bonding layer 1308b (and/or at least one internal conductive feature, such as a BEOL feature) of the upper element 1304 may be tapered or narrowed upwardly, away from the bonding surface 1312b. By way of contrast, at least one conductive feature 1306a in the bonding layer 1308a (and/or at least one internal conductive feature, such as a BEOL feature) of the lower element 1302 may be tapered or narrowed downwardly, away from the bonding surface 1312a. Similarly, any bonding layers (not shown) on the backsides 1316a, 1316b of the elements 1302, 1304 may taper or narrow away from the backsides, with an opposite taper orientation relative to front side conductive features 1306a, 1306b of the same element.

As described above, in an anneal phase of hybrid bonding, the conductive features 1306a, 1306b can expand and contact one another to form a metal-to-metal direct bond. In some embodiments, the materials of the conductive features 1306a, 1306b of opposite elements 1302, 1304 can interdiffuse during the annealing process. In some embodiments, metal grains grow into each other across the bond interface 1318. In some embodiments, the metal is or includes copper, which can have grains oriented along the 1311 crystal plane for improved copper diffusion across the bond interface 1318. In some embodiments, the conductive features 1306a and 1306b may include nanotwinned copper grain structure, which can aid in merging the conductive features during anneal. There is substantially no gap between the non-conductive bonding layers 1308a and 1308b at or near the bonded conductive features 1306a and 1306b. In some embodiments, a barrier layer may be provided under and/or laterally surrounding the conductive features 1306a and 1306b (e.g., which may include copper). In other embodiments, however, there may be no barrier layer under the conductive features 1306a and 1306b.

It is contemplated that any combination of the methods described above may be used to form passive optical elements, displays, and/or display devices whether or not expressly recited herein.

The embodiments discussed above are intended to be illustrative and not limiting. One skilled in the art would appreciate that individual aspects of the passive optical elements, displays, display devices, and methods discussed herein may be omitted, modified, combined, and/or rearranged without departing from the scope of the disclosure.

1-20. (canceled)

21. A display comprising:
a plurality of LEDs; and
a passive optical element attached to a surface of two or more LEDs of the plurality of LEDs, wherein:
the two or more LEDs comprise a first LED and a second LED;
the passive optical element redistributes light emitted from the first LED to exit the display in a first and second region of the display;
the first region of the display corresponds to the first LED; and
the second region of the display corresponds to the second LED.

22. The display of claim 21, wherein:
the passive optical element comprises a first mirror and a second mirror;
the first mirror is a partial mirror that transmits a portion of light emitted from the first LED to exit the display in the first region corresponding to the first LED and reflects a remaining portion of light emitted from the first LED towards the second mirror; and
the second mirror is a full mirror that reflects light from the first mirror to exit the display in the second region corresponding to the second LED.

23. The display of claim 22, wherein the partial mirror is a half mirror that transmits about 50% of light emitted from the first LED and reflects about 50% of light emitted from the first LED.

24. The display of claim 22, wherein the first LED and the second LED are adjacent LEDs of the display.

25. The display of claim 21, wherein:
the two or more LEDs further comprise a third LED; and
the passive optical element transmits light emitted from the third LED to exit the display in a region of the display corresponding to the third LED.

26. The display of claim 25, wherein:
the third LED is between the first LED and the second LED.

27. The display of claim 21, wherein:
the two or more LEDs further comprise a third LED; and
the passive optical element redistributes light emitted from the third LED to exit the display in a third region and the second region of the display, the third region of the display corresponding to the third LED.

28. The display of claim 27, wherein:
the passive optical element comprises a first mirror, a second mirror, a third mirror, and a fourth mirror;
the first mirror is a first partial mirror that transmits a portion of light emitted from the first LED to exit the display in the first region corresponding to the first LED and reflects a remaining portion of light emitted from the first LED towards the second mirror;
the second mirror is a first full mirror that reflects light from the first mirror to exit the second region of the display corresponding to the second LED;
the third mirror is a second partial mirror that transmits a portion of light emitted from the third LED to exit the display in the third region corresponding to the third LED and reflects a remaining portion of light emitted from the third LED towards the fourth mirror; and
the fourth mirror is a second full mirror that reflects light from the third mirror to exit the second region of the display corresponding to the second LED.

29. The display of claim 28, wherein:
the first partial mirror transmits about 75% of light emitted from the first LED and reflects about 25% of light emitted from the first LED; and
the second partial mirror transmits about 75% of light emitted from the third LED and reflects about 25% of light emitted from the third LED.

30. The display of claim 27, wherein:
the two or more LEDs further comprise a fourth LED and a fifth LED;
the passive optical element redistributes light emitted from the fourth LED to exit the display in a fourth region and the second region of the display, the fourth region of the display corresponding to the fourth LED; and
the passive optical element redistributes light emitted from the fifth LED to exit the display in a fifth region and the second region of the display, the fifth region of the display corresponding to the fifth LED.

31. The display of claim 21, wherein:
the two or more LEDs further comprise a third LED;
the passive optical element comprises a brightness enhancement film in a portion of the passive optical element overlapping the third LED when the display is viewed from top down or bottom up; and
the passive optical element enhances light emitted from the third LED to exit the display in a region of the display corresponding to the third LED.

32. The display of claim 22, wherein:
the first mirror comprises a first reflective film on a first portion of a first dielectric layer;
the second mirror comprises a second reflective film on a second portion of the first dielectric layer; and
the passive optical element comprises a second dielectric layer on the first reflective film, the second reflective film, and a third portion of the first dielectric layer; and
the second dielectric layer is polished.

33. The display of claim 32, wherein:
the passive optical element further comprises a substrate attached to the second dielectric layer; and
the passive optical element further comprises a third dielectric layer on a surface of the first dielectric layer that is opposite another surface of the first dielectric layer in contact with the first and second reflective films.

34. The display of claim 33, wherein a surface of the substrate is bonded to the surface of the two or more LEDs.

35. The display of claim 32, wherein a surface of the second dielectric layer is bonded to the surface of the two or more LEDs.

36. The display of claim 21, wherein:
the two or more LEDs further comprise a third LED;
the passive optical element comprises a plurality of optical blocks comprising a splitter block, a waveguide block, and a reflector block;
the splitter block is attached to the surface of the first LED;
the reflector block is attached to the surface of the second LED;
the waveguide block is attached to the surface of the third LED;
the splitter block transmits light emitted from the first LED to exit the display in the first region corresponding to the first LED and reflects a remaining portion of light emitted from the first LED to the waveguide block;
the waveguide block transmits light from the splitter block to the reflector block;
the reflector block reflects the light from the waveguide block to exit the display in the second region corresponding to the second LED; and
the waveguide block receives light from the third LED and transmits the light from the third LED to exit the display in a third region corresponding to the third LED.

37. The display of claim 21, wherein:
the passive optical element comprises a plurality of optical blocks comprising a splitter block and a reflector block;
the splitter block is attached to a surface of the first LED;
the reflector block is attached to a surface of the second LED;
the splitter block transmits a portion light emitted from the first LED to exit the display in the first region corresponding to the first LED and reflects a remaining portion of light emitted from the first LED to the reflector block; and
the reflector block reflects the light from the splitter block to exit the display in the second region corresponding to the second LED.

38. The display of claim 37, wherein:
the passive optical element further comprises a collimating lens;
the collimating lens is attached to the splitter block;
the splitter block reflects the remaining portion of light from the first LED to the collimating lens; and
the collimating lens collimates light exiting the splitter block to the reflector block.

39. The display of claim 37, wherein the first LED and the second LED are separated by a third LED of the plurality of LEDs.

40. The display of claim 22, wherein:
the first mirror is disposed in a first layer stack;
the second mirror is disposed in a second layer stack; and
the passive optical element comprises the first layer stack bonded to the second layer stack.
